(19) United States
(12) Patent Application Publication
(10) Pub. No.: US 2023/0335458 A1
(43) Pub. Date: Oct. 19, 2023

(54) SEMICONDUCTOR DEVICE AND METHOD FOR PRODUCING THE SAME

(71) Applicant: Mitsubishi Electric Corporation, Tokyo (JP)

(72) Inventor: Shota YAMABE, Tokyo (JP)

(73) Assignee: Mitsubishi Electric Corporation, Tokyo (JP)

(21) Appl. No.: 18/096,236

(22) Filed: Jan. 12, 2023

(30) Foreign Application Priority Data
Apr. 19, 2022 (JP) 2022-068650

(51) Int. Cl. H01L 23/367; H01L 23/46

(52) U.S. Cl. CPC H01L 23/3677; H01L 23/46

(57) ABSTRACT

[Subject] The aim is to eliminate the influence on a component mounting surface by burrs and contamination which are produced at the time of metal joining, and to obtain the semiconductor device which can achieve cooling of a power semiconductor at a small size and at a low cost.

[Solution] A semiconductor device, includes: a power semiconductor, a heat sink, having a first surface on which the power semiconductor is provided, and a second surface on which a heat dissipation portion is provided, and a case, made of metal, in which the power semiconductor and the heat sink are stored, wherein, penetrating the case, metal joining between the case and the heat sink is performed.

### FIELD OF THE INVENTION

The present application relates to a semiconductor device and a method for producing the same.

### BACKGROUND OF THE INVENTION

In electrified vehicles, specifically, hybrid vehicles (HV), plug-in hybrid vehicles (PHV, PHEV), electric vehicles (EV), and fuel cell vehicles (FCV), there are provided with semiconductor devices of electric power conversion use, such as an inverter which drives a motor of driving use and a converter which boosts the power supply voltage of batteries. In recent years, there has been, in such semiconductor devices, a tendency toward smaller and higher outputs and lower cost designs. Additionally, the cooling of their electronic components has been performed predominantly based on water cooling.

Moreover, as a production method of a semiconductor device which employs the water cooling system, a technology is disclosed in which metal composition components are joined by a friction stir welding method (Friction Stir Welding, hereinafter referred to as FSW).

For example, as shown in the Patent Document 1, a method is known in which, fins, of a heat dissipation board which is equipped with a component heat dissipation surface and a fin arrangement surface, are arranged so that they may be stored in a case. Additionally, as for the sealing between the heat dissipation board and the case, while the bottom surface of the case is supported, a tool for FSW is applied from an upper part, toward the joining interface between the case and the heat dissipation board, to join them.

### CITATION LIST

### Patent Literature

Patent Document 1: Japanese Patent No. 6512266

### SUMMARY OF THE INVENTION

### Technical Problem

Since the tool for FSW is inserted from a component mounting side to achieve joining, burrs and contamination (metal fragments, foreign matter, and others, which are caused by metal joining) are scattered on the component mounting surface, at the time of metal joining by FSW. The scattered burrs and contamination may damage the component mounting surface. Further, faulty insulation, or breakage by the increased thermal resistance of a component mounting surface may take place, and man-hours for removing burrs and contamination, which are scattered on the component mounting surface side, may be evoked. Therefore, there arises a subject that production cost increases.

The present application is made to solve the problems mentioned above. The aim is to eliminate the influence on the component mounting surface due to the burrs and contamination which are produced at the time of metal joining, and to obtain a semiconductor device which is capable of achieving the cooling of a power semiconductor, at a small size and at a low cost.

### Solution to Problem

A semiconductor device, according to the present application includes:

a power semiconductor,

a heat sink, having a first surface on which the power semiconductor is provided, and a second surface on which a heat dissipation portion is provided, and

a case, made of metal, in which the power semiconductor and the heat sink are stored,

wherein, penetrating the case, metal joining between the case and the heat sink is performed.

### Advantageous Effects of Invention

According to the present application, metal joining is performed between a case and a heat sink, having penetration through the case, where the case stores a power semiconductor and the heat sink. Thereby, influence of burrs and contamination, which are produced when metal joining is performed to the component mounting surface on which a power semiconductor is installed, can be eliminated, and in addition, a simple processing method makes it possible to obtain a semiconductor device which can achieve the cooling of a power semiconductor at a small size and at a low cost.

### BRIEF EXPLANATION OF DRAWINGS

FIG. 1 is a plan view showing the inside of a case of the semiconductor device in accordance with the Embodiment 1 to the Embodiment 5.

FIG. 2 is an elevational view showing the arrangement from the front of the semiconductor device in accordance with the Embodiment 1.

FIG. 3 is a bottom view showing the arrangement from the undersurface of the semiconductor device in accordance with the Embodiment 1.

FIG. 4 is a sectional view showing the A-A section of FIG. 1 of the semiconductor device in accordance with the Embodiment 1.

FIG. 5 is a bottom view showing the arrangement from the undersurface of the semiconductor device in accordance with the Embodiment 2.

FIG. 6 is a sectional view showing the B-B section of FIG. 5 of the semiconductor device in accordance with the Embodiment 2.

FIG. 7 is a bottom view showing the arrangement from the undersurface of the semiconductor device in accordance with the Embodiment 3.

FIG. 8 is a sectional view showing the C-C section of FIG. 7 of the semiconductor device in accordance with the Embodiment 3.

FIG. 9 is a sectional view showing the A-A section of FIG. 1 of the semiconductor device in accordance with the Embodiment 4.

FIG. 10 is a sectional view of a modification example, showing the A-A section of FIG. 1 of the semiconductor device in accordance with the Embodiment 4.

FIG. 11 is a sectional view showing the A-A section of FIG. 1 of the semiconductor device in accordance with the Embodiment 5.

### DESCRIPTION OF EMBODIMENTS

### Embodiment 1

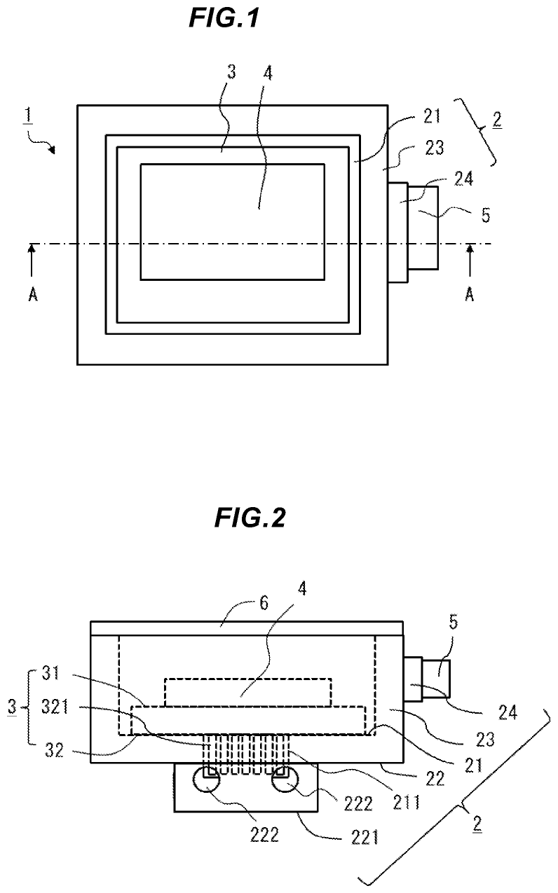

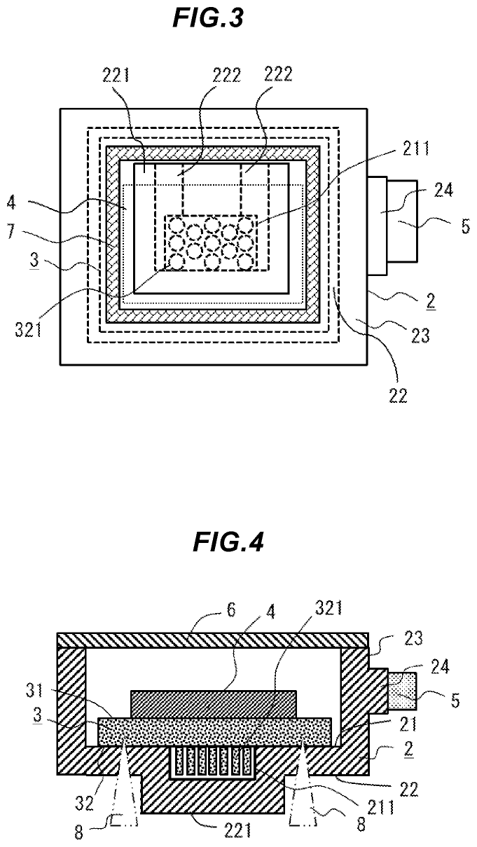

The Embodiment 1 of the present application will be explained based on FIG. 1 to FIG. 4. FIG. 1 is a plan view showing the arrangement inside the case of a semiconductor device of the present application, and FIG. 2 is an elevational view of the semiconductor device in accordance with the Embodiment 1, and FIG. 3 is a bottom view thereof, and FIG. 4 is a sectional view which shows the A-A section of FIG. 1.

In FIG. 1 and FIG. 2, the semiconductor device 1 is constituted of a case 2, a heat sink 3, a power semiconductor 4, a connector 5 for making electric connection with an outside, and a lid 6 (FIG. 1 shows a state in which the lid 6 is removed).

Using a metal material, the case 2 is formed by aluminum die-cast molding, which has a high degree of shape freedom. The case has a first surface 21 which is in contact with the heat sink 3, and a second surface 22 which is the opposite surface of the first surface 21. At least in one part of the second surface 22 of the case 2, an overhang portion 221 is formed. Additionally, in the overhang portion 221, headers 222 are formed which are the gateways for feeding in and feeding out cooling medium. A groove portion 211 and a wall portion 23, which constitutes the outer periphery of the case 2, are formed on the first surface 21 of the case 2. The groove portion 211 is toward the overhang portion 221 which is formed on the second surface 22 of the case 2. Further, the groove portion is formed to be connected with the headers 222. The wall portion 23 is formed from the outer side, rather than the outside shape of the heat sink 3. Further, the wall portion forms a face which fixes the lid 6 at least at the tip of the wall portion 23, and a holding portion 24 which fixes the connector 5 at least at a part of the side surface thereof is formed.

The heat sink 3 is formed from a metal material (for example, aluminum) which has a higher thermal conductivity rather than the case 2. Additionally, the heat sink has a first surface 31 for mounting a power semiconductor 4, and a second surface 32 which is the opposite surface of the first surface 31. On the surface of the first surface 31 on which the power semiconductor 4 is mounted, plating (not illustrated) is conducted. The second surface 32 is constituted of a surface which is in contact with the first surface 21 of the case 2, and fins 321 which serve as a heat dissipation portion. Those fins are formed so as to be stored in the groove portion 211, which is formed on the first surface 21 of the case 2.

The power semiconductor 4 includes a built in semiconductor element (illustration is omitted). The semiconductor element is, for example, a MOS-FET, an IGBT, and a diode, and as their base materials, besides silicon, next-generation semiconductors, such as silicon carbide, and gallium nitride, are used. The bottom surface of the power semiconductor 4 and the first surface 31 of the heat sink 3 are metal joined, and a heat sink ASSY which is a combination component is formed.

In FIG. 3 and FIG. 4, a state is shown in which the case 2 and the heat sink 3 are metal joined, by the tool for FSW, or the energy irradiation 8. The heat sink ASSY and the case 2 are metal joined, having penetration through the case 2, at the contact part of the second surface 32 of the heat sink 3 and the first surface 21 of the case 2, where the tool for FSW which is the friction-stir welding, or the energy irradiation 8 is conducted (refer to FIG. 4), from the second surface 22 which is the outside of the case 2, to a part which is the outside of the groove portion 211 of the case 2 and the headers 222, and in addition, has a uniformed wall thickness. This metal joining seals the groove portion 211 of the case 2 and the second surface 32 of the heat sink 3, and a sealed and closed space is formed. In FIG. 3, shown are metal joining marks 7 which are caused by the tool for FSW, or the energy irradiation 8. As shown in the drawing, the circumference of fins 321 which are the heat dissipation portion of the heat sink 3 and the headers 222 which are the gateways of the cooling medium to the case 2 is sealed by metal joining.

In the drawing, pipes which will be connected to the headers 222 of the case 2 are omitted. However, a closed space through which the cooling medium flows is formed by the above configuration. The cooling medium passes, from the pipe, through the header 222 which is provided in the case 2 and becomes a feed in port. Additionally, the cooling medium passes the closed space which is formed by the groove portion 211 of the case 2 sealed with the first surface 21 of the case 2 and the second surface 32 of the heat sink 3, and the second surface 32 of the heat sink 3, where the fins 321 are formed. Furthermore, the cooling medium passes through the other header 222 which is provided in the case 2 and becomes a feed out port, and flows through a cooling medium channel which is connected to a pipe. Since the circumference along which the cooling medium channel passes is metal joined for processing use, a configuration is achieved in which the cooling medium does not leak to the outside.

In FIG. 3, a drawing is shown in which, in relation to the metal joining part of the case 2 and the heat sink 3, the whole circumference of metal joining marks 7 can be checked on the second surface 22 of the case 2. However, it is allowed that metal joining marks 7 cannot be seen on the surface, due to a removal processing of at least a part of the surface, like a cutting processing and others. Moreover, when a pipe is provided in the side-face side of a header 222 provided in the case 2, and extends in the plane direction, it is desirable to mount the pipe in a header 222 provided in the case 2, after the heat sink 3 and the case 2 is metal joined.

As for the metal joining between the heat sink 3 and the power semiconductor 4, for example, sinter joining, solder joining, and brazing, are desirable, where joining material is heated to achieve a joining, and then, the whole contact surface is joined, and reduction of heat resistance can be expected in the metal joining.

As for the metal joining between the heat sink 3 and the case 2, base material joining is desirable, for example, the friction-stir welding which uses a tool for FSW, or energy irradiation like laser welding and others, where the base material joining has a metal melt extending to a deep area and a high joining strength.

As for at least one part of the fins 321 which are the heat dissipation portion formed in the heat sink 3, desirable is a projection of plate like shape with a large cooling area, or a projection of pin like shape. For example, it is allowed that narrow pitched pin fins may be formed by forge.

In addition to the production method in which the heat sink ASSY which includes the metal joined power semiconductor 4 and the heat sink 3 is metal joined with the case 2, a production method may be used where, after the heat sink 3 and the case 2 is metal joined, metal joining of the power semiconductor 4 with the heat sink 3 is performed.

The semiconductor device in accordance with the Embodiment 1 of the present application which is described above involves the following effects.

The case 2 and the heat sink 3 are metal joined by the tool for FSW, or the energy irradiation 8, from the second surface 22, which becomes the outside of the case 2. Since burrs and contamination are not produced at the side of the heat sink 3, yield can be improved by the fault control of burrs and contamination, and productivity improvement can be achieved by assembly improvement, which is induced by the reduction of removal work of burrs and contamination.

Since the case 2 is a die-casting molded product, it becomes easy to form at a low cost, the groove portion 211, the wall portion 23, the holding portion 24 of the connector 5, the overhang portion 221, and the header 222. Moreover, the shape of the lid 6 can also be simplified.

Since metal joining between the case 2 and the heat sink 3 is performed in the uniformed wall thickness part of the case 2, the joining depth of metal joining can be reduced. Furthermore, the reduction of machining time and life improvement of a processing tool can be achieved, and the generation of voids at the time of die-casting molding of the case 2 can be suppressed.

Since the case 2 is a die-casting molded product, there is a concern that there will be a fault in leakage (leak of the cooling medium, etc.) to the inside of a product, due to cast void. However, the case 2 and the heat sink 3 are metal joined from the second surface 22 of the case 2, by the tool for FSW, or the energy irradiation 8. Then, cast voids can be crushed, and the course of leak to the inside of a product can be eliminated, and the concerns about the leakage inside the product is eliminated.

Since the heat sink 3, which is metal joined with the power semiconductor 4, has a higher thermal conductivity, rather than the case 2, it becomes easy to cool the power semiconductor 4.

The fins 321 are formed in at least one part of the heat dissipation portion of the heat sink 3. Then, cooling capacity of the heat sink 3 can be further improved, and cooling of the metal joined power semiconductor 4 becomes easy to perform.

When the heat sink 3 is formed by forge to have fins 321, which are formed with pin fins of a narrow pitch, the cooling capacity of the heat sink 3 can be further improved, and cooling of the metal joined power semiconductor 4 becomes easy to perform.

The heat sink 3 is metal joined with the power semiconductor 4, the heat resistance between the heat sink 3 and the power semiconductor 4 is reduced, and it becomes easy to cool a power semiconductor.

When a pipe is press fitted in the header 222, it become easy to conduct the connection with a component which feeds in the cooling medium from the outside and feeds it out. In addition, when the shape of the pipe employs an L shaped bending form, it becomes easy to respond to also at the time of design change.

Since the cooling medium channel becomes a closed space made by metal joining, it becomes possible to prevent the outflow of the cooling medium from a metal joining part to a closed space outside.

In the state where the heat sink 3 and the power semiconductor 4 in which large current flows constitute a combination component, the heat sink and the power semiconductor are metal joined with the case 2. Then, without considering the heat capacity of the case 2, metal joining between the heat sink 3 and the power semiconductor 4 can be performed. Further, the degree of freedom in the of choice of metal joining methods is increased. For example, solder joining in which metal joining is performed by heating, and low thermal resistance metal joining, like silver sinter joining, become easy to conduct, and the cooling of the power semiconductor 4 becomes easy to conduct.

The heat sink 3 and the power semiconductor 4 are metal joined, before carrying out the metal joining with the case 2. Then, since it is possible to conduct a good product inspection by the thermal resistance, in the state of the combination component composed of the heat sink 3 and the power semiconductor 4, productivity can be improved.

When a production method is employed in which, after the case 2 and the heat sink 3 are metal joined, metal joining of the power semiconductor 4 is performed with the heat sink 3, poor joining between the case 2 and the heat sink 3 can be grasped, before metal joining of the power semiconductor 4 is performed. Then, the failure of the power semiconductor 4 can be prevented.

When a pipe is provided on the side-face side of the header 222 prepared in the case 2, and extends in the plane direction, the pipe is mounted in the header 222 prepared in the case 2, after metal joining between the heat sink 3 and the case 2 is performed. Thereby, since the metal joining range of the case 2 and the heat sink 3 can be minimized, the machining time of metal joining can be reduced.

Regarding the metal joining part between the case 2 and the heat sink 3, a state is created in which metal joining marks 7 remain on the second surface 22 of the case 2. Thereby, joining states including the presence or absence of joining and joining defects can be confirmed at a glance, and confirmation in processes becomes easy to perform. Moreover, the cost for carrying out the addition removal processing can be reduced.

The fins 321 of the second surface 32 of the heat sink 3 are formed so that they may be stored in the groove portion 211 which is formed in the first surface 21 of the case 2. Thereby, the fins can have a role for positioning the case 2 and the heat sink 3, and assembly can be made easy to perform.

### Embodiment 2

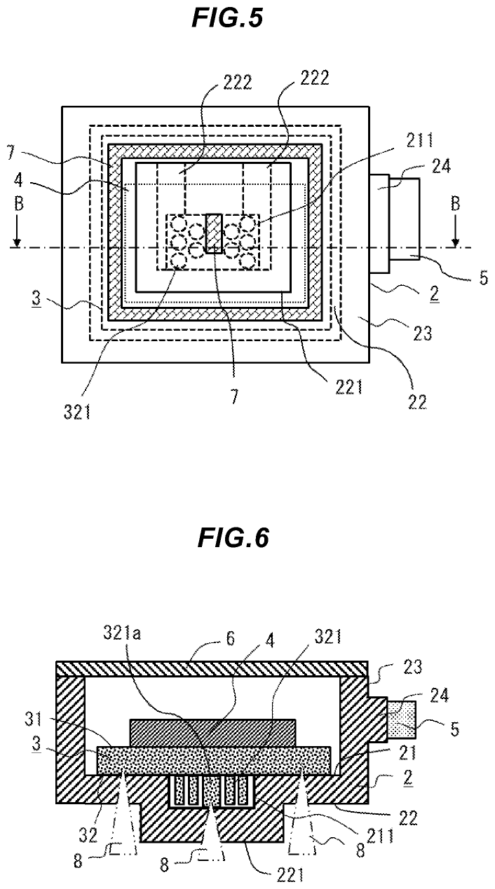

Hereinafter, explanation will be made about the semiconductor device in accordance with the Embodiment 2, using FIG. 5 and FIG. 6. Portions which are different from the Embodiment 1 will be explained mainly. The same symbol is attached to the portion which is the same with, or corresponds to the Embodiment 1, and explanation thereabout is omitted.

In FIG. 5 and FIG. 6, fins 321, which are the heat dissipation portion, are formed on the second surface 32 of the heat sink 3. A projection portion 321a between the fins 321 is in contact with the bottom surface of the groove portion 211 constructed on the first surface 21 of the case 2. Furthermore, in the contact part where the projection portion 321a between the fins 321, which are formed on the second surface 32 of the heat sink 3, is in contact with the bottom surface of the groove portion 211 constructed on the first surface 21 of the case 2, the tool for FSW, or the energy irradiation 8 is conducted from the overhang portion 221, which is formed on the second surface 22 of the case 2, and at least one part thereof is metal joined.

According to the present Embodiment 2, the fins 321, or the heat dissipation portion, are formed on the second surface 32 of the heat sink 3, and the projection portion 321a between the fins 321 is in contact with the bottom surface of the groove portion 211 constructed on the first surface 21 of the case 2. Thereby, cooling medium can divide the space of the fins 321 and the bottom surface of the groove portion 211, and a part of the cooling medium channel. In addition, the flow of the cooling medium is changed, and the rectification of the cooling medium, and partial concentration and diffusion of the cooling medium, are possible, and then, the reduction of pressure loss can be performed. Moreover, the flow of the cooling medium can be adjusted, which is necessary with respect to components, such as the power semiconductor 4 mounted in the heat sink 3.

In the contact part where the projection portion 321a between fins 321, which are formed on the second surface 32 of the heat sink 3, is in contact with the bottom surface of the groove portion 211 constructed on the first surface 21 of the case 2, the tool for FSW, or the energy irradiation 8 is conducted from the overhang portion 221 which is formed in the second surface 22 of the case 2, and at least one part is metal joined. Then, since the joining points between the case 2 and the heat sink 3 can be increased, joining strength can be increased.

It is worth noticing that, when the projection portion 321a is not specially formed between the fins 321, or the heat dissipation portion, which are formed on the second surface 32 of the heat sink 3, the same effect will be acquired, if the tool for FSW, or the energy irradiation 8 is conducted, in the contact part where the fins 321 are in contact with the bottom surface of the groove portion 211 which is constructed on the first surface 21 of the case 2.

### Embodiment 3

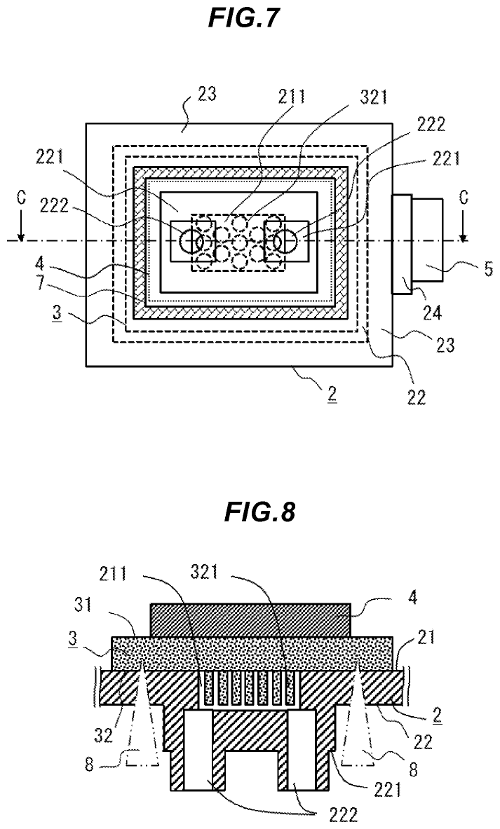

Hereinafter, explanation will be made about the semiconductor device in accordance with the Embodiment 3, using FIG. 7 and FIG. 8. Portions which are different from the Embodiment 1 will be explained mainly. The same symbol is attached to the portion which is the same with, or corresponds to the Embodiment 1, and explanation thereabout is omitted.

In FIG. 7 and FIG. 8, headers 222 are formed on the bottom surface of the overhang portion 221, which is formed on the second surface 22 of the case 2. In the headers 222, pipes (illustration is omitted) are mounted which feed in and feed out the cooling medium. In FIG. 7 and FIG. 8, the headers 222 of feed in use and feed out use are both formed in the bottom surface. However, the combination with headers which are arranged at a side face of the overhang portion, like in the Embodiment 1, may be allowed. Moreover, in the headers 222, pipes which feed in and feed out the cooling medium are mounted. However, in combination with the Embodiment 1, air valves which extract the air inside the cooling medium channel may be attached to the side-face side of the overhang portion.

According to the Embodiment 3, the headers 222 are formed in the overhang portion 221 of the case 2, and the headers 222 do not project in the plane direction. Thereby, since the area of metal joining between the case 2 and the heat sink 3 can be minimized, the machining time of metal joining can be decreased.

Since feed in and feed out of the cooling medium become easy to conduct, it becomes possible to reduce design man days, at the time of a design change. When air valves are mounted, the air inside the cooling medium channel can be removed. Thereby, it becomes possible to prevent the fall of the cooling capability due to the off-centered flow of the cooling medium, caused by the air inside the cooling medium channel; and faults, such as, the breakage of the cooling medium channel, due to vibrations and shocks.

### Embodiment 4

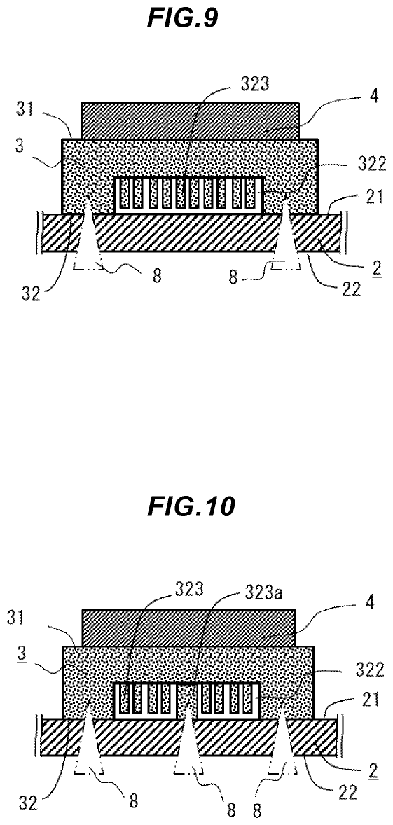

Hereinafter, explanation will be made about the semiconductor device in accordance with the Embodiment 4, using FIG. 9 and FIG. 10. Portions which are different from the Embodiment 1 will be explained mainly. The same symbol is attached to the portion which is the same with, or corresponds to the Embodiment 1, and explanation thereabout is omitted.

In FIG. 9, a groove portion 322 is formed on the second surface 32 of the heat sink 3. On the inside of the groove portion 322, fins 323 are formed, which are the heat dissipation portion. The groove portion 322 and the first surface 21 of the case 2 are metal joined and sealed, where the tool for FSW, or the energy irradiation 8 is conducted to penetrate the case 2, from the second surface 22, which is the outside of the case 2.

Moreover, in FIG. 10, a projection portion 323a, which is between the fins 323 formed on the inside of the groove portion 322 of the heat sink 3, is in contact with the first surface 21 of the case 2. Furthermore, in the contact part where the projection portion 323a, which is between the fins 323 formed on the inside of the groove portion 322 of the heat sink 3, is in contact with the first surface 21 of the case 2, the tool for FSW, or the energy irradiation 8 is conducted, from the second surface 22 which is the outside of the case 2, and at least one part thereabout is metal joined.

According to this Embodiment 4, the area of the heat sink 3 through which the cooling medium flows increases. Thereby, the cooling capacity of the heat sink 3 can be raised, and it becomes easy to cool the power semiconductor 4.

Moreover, the projection portion 323a, which is between the fins 323 formed on the inside of the groove portion 322 of the heat sink 3, is in contact with the first surface 21 of the case 2. Thereby, the cooling medium can divide the space of the fins 323 and the first surface 21 of the case 2, and a part of the cooling medium channel, and the flow of the cooling medium is changed. Additionally, since the rectification of the cooling medium, and partial concentration and diffusion of the cooling medium are possible, and then, the reduction of pressure loss can be achieved. Moreover, it becomes possible to adjust the flow of the cooling medium, which is necessary with respect to components, such as the power semiconductor 4 mounted in the heat sink 3.

Fins 323, or the heat dissipation portion, are formed on the inside of the groove portion 322 of the heat sink 3. In the contact part where the projection portion 323a between the fins 323 is in contact with the first surface 21 of the case 2, the tool for FSW, or the energy irradiation 8 is conducted from the second surface 22 which is the outside of the case 2, and at least one part is metal joined. Thereby, since joining parts between the case 2 and the heat sink 3 can be increased, joining intensity can be increased.

It is worth noticing that, when the projection portion 323a is not specially formed between the fins 323, which are the heat dissipation portion formed into the groove portion 322 of the heat sink 3, the same effect will be acquired, if the tool for FSW, or the energy irradiation 8 is conducted, in the contact part where the fins 323 are in contact with the first surface 21 of the case 2.

### Embodiment 5

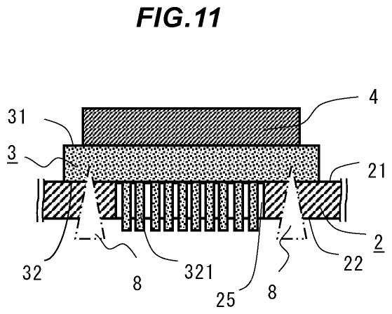

Hereinafter, explanation will be made about the semiconductor device in accordance with the Embodiment 5, using FIG. 11. Portions different from the Embodiment 1 is explained mainly. The same symbol is attached to the portion which is the same with, or corresponding to the Embodiment 1, and explanation thereabout is omitted.

In FIG. 11, a through hole 25 which becomes a gateway of the cooling medium, is formed in part, from the first surface 21 of the case 2 to the second surface 22 of the case 2. The outside of the heat sink 3 is larger than the project area of the through hole 25 constructed in the case 2. In the first surface 21 of the case 2 and the second surface 32 of the heat sink 3, from the second surface 22 which is the outside of the case 2, toward the heat sink 3, the tool for FSW, or the energy irradiation 8 is conducted on the circumference of the through hole 25 of the case 2, and metal joining is achieved. The first surface 21 of the case 2 and the second surface 32 of the heat sink 3 are sealed by this metal joining. The heat sink 3 is exposed from the side of the second surface 22 which is the outside of the case 2. Fins 321 are formed from the exposed second surface 32 of the heat sink 3, and the fins are exposed to the outside of the case 2.

According to the present Embodiment 5, it becomes easy to form the configuration in which, even if the cooling medium is applied directly from the outside of the case 2, the cooling medium does not leak to the mounting face side of the power semiconductor 4. Even when the cooling medium flows in a case which is different from the case 2, it is possible to respond to the difference easily. For example, even when the cooling medium is air, and headers are unnecessary, it is possible to respond to the change easily.

In the above mentioned Embodiment 1 to Embodiment 5, the language that a power semiconductor 4 is directly joined with a heat sink 3 includes also the case where a modularized (packaged) power semiconductor 4 is directly joined with a heat sink 3.

Moreover, the power semiconductor 4 may be a semiconductor element itself, and metal joining may be performed between the bottom surface of a semiconductor element and the first surface 31 of the heat sink 3.

Although the present application is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations to one or more of the embodiments. It is therefore understood that numerous modifications which have not been exemplified can be devised without departing from the scope of the present application. For example, at least one of the constituent components may be modified, added, or eliminated. At least one of the constituent components mentioned in at least one of the preferred embodiments may be selected and combined with the constituent components mentioned in another preferred embodiment.

As mentioned above, explanation is made in full detail about desirable Embodiments and the like. However, the present application is not restricted to the above Embodiments and the like. Additionally, various modifications and substitutions can be added to the Embodiments and the like, which were mentioned above, without deviating from the scope indicated in the patent claims.

Hereinafter, the various modes of the present disclosure are summarized below, as additional remarks.

### (Additional Remark 1)

A semiconductor device, comprising:

a power semiconductor,

a heat sink, having a first surface on which the power semiconductor is provided, and a second surface on which a heat dissipation portion is provided, and

a case, made of metal, in which the power semiconductor and the heat sink are stored,

wherein, penetrating the case, metal joining between the case and the heat sink is performed.

### (Additional Remark 2)

The semiconductor device according to Additional remark 1,

wherein a first surface of the case is in contact with the second surface of the heat sink,

on a second surface of the case, which becomes an outside of the case, gateways of cooling medium which cools the heat dissipation portion are provided, and

between the first surface of the case and the second surface of the heat sink, the circumference of the heat dissipation portion and the gateways is sealed by the metal joining.

### (Additional Remark 3)

The semiconductor device according to Additional remark 2,

wherein, on the first surface of the case, a groove portion which stores the heat dissipation portion is provided.

### (Additional Remark 4)

The semiconductor device according to Additional remark 2,

wherein, on the second surface of the heat sink, a groove portion which has the heat dissipation portion is provided.

### (Additional Remark 5)

The semiconductor device according to any one of Additional remarks 2 to 4,

wherein the gateways provided on the second surface of the case penetrate through the first surface of the case.

### (Additional Remark 6)

The semiconductor device according to Additional remark 5,

wherein the heat dissipation portion is exposed from the gateways toward the outside of the case.

### (Additional Remark 7)

The semiconductor device according to any one of Additional remarks 2 to 6,

wherein the heat dissipation portion is made from a plurality of fins of plate shape or pin shape.

### (Additional Remark 8)

The semiconductor device according to Additional remark 7,

wherein the second surface of the heat sink has a projection portion, from between the fins which are provided in plural, toward the first surface of the case or the groove portion provided on the first surface of the case.

### (Additional Remark 9)

The semiconductor device according to Additional remark 8,

wherein a part of the fins or the projection portion is in contact with the first surface of the case or the bottom surface of the groove portion provided on the first surface of the case, and is performed of metal joining with the case.

### (Additional Remark 10)

The semiconductor device according to any one of Additional remarks 2 to 9,

wherein the case is a die-cast molded product.

### (Additional Remark 11)

The semiconductor device according to Additional remark 10,

wherein the case has a uniformed wall thickness, within an area in which the metal joining is performed with the heat sink.

### (Additional Remark 12)

The semiconductor device according to any one of Additional remarks 2 to 11,

wherein the gateways have a header which is a feed in port of the cooling medium, and a header which is a feed out port of the cooling medium.

### (Additional Remark 13)

The semiconductor device according to Additional remark 12,

wherein pipes are joined to the headers which are provided in the gateways, and feed in and feed out of the cooling medium is achieved through the pipes.

### (Additional Remark 14)

The semiconductor device according to Additional remarks 2 to 13,

wherein the case has, on the first surface, a wall portion which covers outer peripheries of the heat sink and the power semiconductor, and

an end part of the wall portion is sealed with a lid.

### (Additional Remark 15)

The semiconductor device according to any one of Additional remarks 2 to 14,

wherein the power semiconductor is solder joined with the heat sink.

### (Additional Remark 16)

The semiconductor device according to any one of Additional remarks 2 to 15,

wherein, on the second surface of the case, metal joining marks by the metal joining are formed.

### (Additional Remark 17)

A method for producing a semiconductor device, where the semiconductor device is according to any one of Additional remarks 2 to 16, the method comprising:

a first joining process for joining the power semiconductor and the heat sink as a combination component, and

a second joining process for metal joining the case and the heat sink of the combination component.

### (Additional Remark 18)

A method for producing a semiconductor device, where the semiconductor device is according to Additional remarks 2 to 16, the method comprising:

a first joining process for metal joining the case and the heat sink as a combination component, and

a second joining process for joining the power semiconductor on the first surface of the heat sink of the combination component.

### (Additional Remark 19)

The method for producing a semiconductor device according to Additional remark 17 or Additional remark 18,

wherein the metal joining is performed by friction-stir welding or energy irradiation.

### EXPLANATION OF NUMERALS AND SYMBOLS

1 Semiconductor Device: 2 Case: 21 First Surface: 211 Groove Portion: 22 Second Surface: 221 Overhang Portion: 222 Header: 23 Wall Portion: 24 Holding Portion 25 Through Hole: 3 Heat Sink: 31 First Surface: 32 Second Surface: 321 Fin: 321a Projection Portion: 322 Groove Portion: 323 Fin: 323a Projection Portion: 4 Power Semiconductor: 5 Connector: 6 Lid: 7 Metal Joining Mark: 8 Tool for FSW, or Energy Irradiation.

What is claimed is:

1. A semiconductor device, comprising:
a power semiconductor,
a heat sink, having a first surface on which the power semiconductor is provided, and a second surface on which a heat dissipation portion is provided, and
a case, made of metal, in which the power semiconductor and the heat sink are stored,
wherein, penetrating the case, metal joining between the case and the heat sink is performed.

2. The semiconductor device according to claim 1,
wherein a first surface of the case is in contact with the second surface of the heat sink,
on a second surface of the case, which becomes an outside of the case, gateways of cooling medium which cools the heat dissipation portion are provided, and
between the first surface of the case and the second surface of the heat sink, the circumference of the heat dissipation portion and the gateways is sealed by the metal joining.

3. The semiconductor device according to claim 2,
wherein, on the first surface of the case, a groove portion which stores the heat dissipation portion is provided.

4. The semiconductor device according to claim 2,
wherein, on the second surface of the heat sink, a groove portion which has the heat dissipation portion is provided.

5. The semiconductor device according to claim 2,
wherein the gateways provided on the second surface of the case penetrate through the first surface of the case.

6. The semiconductor device according to claim 5,
wherein the heat dissipation portion is exposed from the gateways toward the outside of the case.

7. The semiconductor device according to claim 2,
wherein the heat dissipation portion is made from a plurality of fins of plate shape or pin shape.

8. The semiconductor device according to claim 7,
wherein the second surface of the heat sink has a projection portion, from between the fins which are provided in plural, toward the first surface of the case or the groove portion provided on the first surface of the case.

9. The semiconductor device according to claim 8,
wherein a part of the fins or the projection portion is in contact with the first surface of the case or the bottom surface of the groove portion provided on the first surface of the case, and is performed of metal joining with the case.

10. The semiconductor device according to claim 1,
wherein the case is a die-cast molded product.

11. The semiconductor device according to claim 1,
wherein the case has a uniformed wall thickness, within an area in which the metal joining is performed with the heat sink.

12. The semiconductor device according to claim 2,
wherein the gateways have a header which is a feed in port of the cooling medium, and a header which is a feed out port of the cooling medium.

13. The semiconductor device according to claim 12,
wherein pipes are joined to the headers which are provided in the gateways, and feed in and feed out of the cooling medium is achieved through the pipes.

14. The semiconductor device according to claim 2,
wherein the case has, on the first surface, a wall portion which covers outer peripheries of the heat sink and the power semiconductor, and
an end part of the wall portion is sealed with a lid.

15. The semiconductor device according to claim 1,
wherein the power semiconductor is solder joined with the heat sink.

16. The semiconductor device according to claim 2,
wherein, on the second surface of the case, metal joining marks by the metal joining are formed.

17. A method for producing a semiconductor device, where the semiconductor device is according to claim 1, the method comprising:
a first joining process for joining the power semiconductor and the heat sink as a combination component, and
a second joining process for metal joining the case and the heat sink of the combination component.

18. A method for producing a semiconductor device, where the semiconductor device is according to claim 1, the method comprising:
a first joining process for metal joining the case and the heat sink as a combination component, and
a second joining process for joining the power semiconductor on the first surface of the heat sink of the combination component.

19. The method for producing a semiconductor device according to claim 17,
wherein the metal joining is performed by friction-stir welding or energy irradiation.

20. The method for producing a semiconductor device according to claim 18,
wherein the metal joining is performed by friction-stir welding or energy irradiation.
